(19) United States
(12) Patent Application Publication
(10) Pub. No.: US 2025/0391753 A1
(43) Pub. Date: Dec. 25, 2025

(54) PACKAGE STRUCTURE AND MANUFACTURING METHOD THEREOF

(71) Applicant: JCET Management Co., Ltd., SHANGHAI CITY (CN)

(72) Inventors: Xiao GU, SHANGHAI CITY (CN); Lihong LIU, SHANGHAI CITY (CN); Jiongjiong GU, SHANGHAI CITY (CN)

(73) Assignee: JCET Management Co., Ltd., SHANGHAI CITY (CN)

(21) Appl. No.: 19/246,713

(22) Filed: Jun. 24, 2025

(30) Foreign Application Priority Data
Jun. 24, 2024 (CN) 202410819038.5

(51) Int. Cl. H01L 23/498; H01L 21/56; H01L 23/31

(52) U.S. Cl. CPC H01L 23/49811; H01L 21/561; H01L 23/3135; H01L 23/49833

(57) ABSTRACT

The present disclosure relates to the technical field of packaging, and provides a package structure and a related manufacturing method thereof. The package structure includes: a first redistribution structure; a second redistribution structure located on a surface of the first redistribution structure, where the second redistribution structure includes a thin film passive component; a first conductive pillar located on a surface of the second redistribution structure; a chip located on a surface of the first conductive pillar; and a molding layer that is located on the surface of the second redistribution structure and that encapsulates the chip and the first conductive pillar. A size and a thickness of the package are reduced, and the number of I/Os of the package is increased; heat dissipation performance of the package is better; and performance consistency is better.

### CROSS-REFERENCE TO RELATED APPLICATION

This application claims priority under 35 U.S.C. § 119 (a) to Chinese Patent Application No. CN202410819038.5, filed on Jun. 24, 2024. The entire content of the above-identified application is incorporated herein by reference.

### TECHNICAL FIELD

The present disclosure relates to the technical field of packaging, and specifically to a package structure and a manufacturing method thereof.

### BACKGROUND

With the increasing requirements of electronic products for packaging integration, SiP emerges, which greatly reduces sizes of electronic devices. However, as end products tend to be thinner and lighter, it is difficult to further reduce the size of the SiP. For example, FIG. 1, is a schematic diagram of a conventional package structure, which includes a substrate 10 and a chip 20 and a passive component 30 that are located on a surface of the substrate. It can be seen that because the package thickness is limited by a height of a component, a thickness of the substrate thickness cannot be further reduced, and the passive component 30 occupies most of the substrate area, and the space left for the chip is small, and even the number of I/Os is limited. In addition, under the condition that the substrate area is insufficient, chips need to be installed on both sides of the substrate, which results in poor heat dissipation. In addition, because the chip 20 and a number of different types of passive components 30 are mounted on the surface of the substrate, the package structure is bent and deformed due to unbalanced stress on the package structure caused by mismatch of a thermal expansion coefficient between the chip 20 and the substrate 10 and mismatch of a thermal expansion coefficient between the passive component 30 and the substrate 10, and then warpage destroys coplanarity of each connection point. Consequently, excessive warpage may lead to disconnection between the chip, the passive component, and the substrate.

### SUMMARY

The present disclosure provides a package structure and a related manufacturing method thereof, which aims to solve the problem that it is difficult to further reduce a size of an existing package structure.

To achieve the foregoing objective, the present disclosure provides a package structure, which includes:
a first redistribution structure;
a second redistribution structure located on a surface of the first redistribution structure, where the second redistribution structure includes a thin film passive component;
a first conductive pillar located on a surface of the second redistribution structure;
a chip located on a surface of the first conductive pillar; and
a molding layer that is located on the surface of the second redistribution structure and that encapsulates the chip and the first conductive pillar.

Preferably, the molding layer includes a first molding layer and a second molding layer, where
the first molding layer is located on the surface of the second redistribution structure, and the surface of the first conductive pillar is exposed out of the first molding layer; and
the second molding layer is located on a surface of the first molding layer and encapsulates the chip.

Preferably, the second redistribution structure includes a plurality of second redistribution layers, where
each second redistribution layer includes a second dielectric layer and a second conductive line extending through the second dielectric layer, and there is at least one thin film passive component.

Preferably, solder balls are arranged on a side surface that is of the first redistribution structure and that is away from the second redistribution structure.

Preferably, the package structure further includes:
an insulation structure that is located on the surface of the first redistribution structure and that is also located on the outer side of the second redistribution structure; and
a second conductive pillar that is located on the surface of the first redistribution structure and passes through the insulation structure, where
the chip is also located on a surface of the second conductive pillar.

Preferably, the molding layer includes a first molding layer and a second molding layer, where
the first molding layer is located on surfaces of the second redistribution structure and the insulation structure, and encapsulates the second redistribution structure, the insulation structure, the first conductive pillar, and the second conductive pillar, and the surface of the first conductive pillar and the surface of the second conductive pillar are exposed out of the first molding layer; and
the second molding layer is located on a surface of the first molding layer and encapsulates the chip.

Correspondingly, the present disclosure further provides a manufacturing method for a package structure, including:
providing a temporary carrier board;
forming an adhesive layer on a surface of the temporary carrier board;
forming a first redistribution structure on a surface of the adhesive layer:
forming, on a surface of the first redistribution structure, a second redistribution structure and a first conductive pillar located on a surface of the second redistribution structure, where the second redistribution structure includes a thin film passive component; and
arranging a chip on a surface of the first conductive pillar, and forming, on the surface of the second redistribution structure, a molding layer for packaging the chip and the first conductive pillar.

Preferably, the step of forming, on the surface of the first redistribution structure, the second redistribution structure and the first conductive pillar located on the surface of the second redistribution structure includes:
forming, on the surface of the first redistribution structure, a second redistribution structure, an insulation structure located on the outer side of the second redistribution structure, and a second conductive pillar passing through the insulation structure, and forming a first conductive pillar on the surface of the second redistribution structure, where the first conductive pillar and the second conductive pillar are used for electrically connecting to the chip.

Preferably, the second redistribution structure, the insulation structure, and the second conductive pillar located in the insulation structure are formed through stacking layer by layer.

Preferably, the step of arranging the chip on the surface of the first conductive pillar, and forming, on the surface of the second redistribution structure, the molding layer for packaging the chip and the first conductive pillar includes:
forming, on the surface of the second redistribution structure, a first molding layer for packaging the first conductive pillar, where the surface of the first conductive pillar is exposed out of the first molding layer;
arranging the chip on the surface of the first conductive pillar; and
forming, on the surface of the first molding layer, a second molding layer for packaging the chip.

Preferably, after forming of the molding layer, the method further includes:
removing the temporary carrier board and the adhesive layer; and
forming solder balls on a side surface that is of the first redistribution structure and that is away from the second redistribution structure. The present disclosure has the following beneficial effects:

The present disclosure provides a package structure and a related manufacturing method thereof. The package structure includes: a first redistribution structure; a second redistribution structure located on a surface of the first redistribution structure, where the second redistribution structure includes a thin film passive component; a first conductive pillar located on a surface of the second redistribution structure; a chip located on a surface of the first conductive pillar; and a molding layer that is located on the surface of the second redistribution structure and that encapsulates the chip and the first conductive pillar. A size and a thickness of the package are reduced, and the number of I/Os of the package is increased. In addition, the chip is packaged above the second redistribution structure through the first conductive pillar, and conventional passive components are replaced with thin film passive components, so that there is space for more chips on one side surface of the substrate, heat dissipation performance of the package is better, a transmission path of an electrical signal is greatly shortened, and a transmission loss of the electrical signal is reduced. Further, parasitic parameters of the thin film passive components are small, and performance consistency is better by combining thin film passive components into a complete package structure. In addition, in the present disclosure, the insulation structure made of a same material as the second dielectric layer in the second redistribution structure is formed on the outer side of the second redistribution structure, and the height of the insulation structure is adjusted, so that stress balance is achieved between a combination of the insulation structure in an edge area of the package structure and the second conductive pillar and the second redistribution structure in the middle area, and the package structure is prevented from warping due to stress imbalance.

### BRIEF DESCRIPTION OF DRAWINGS

FIG. 1 is a schematic diagram of a conventional package structure;

FIG. 2 is a schematic diagram of a second redistribution structure in a package structure according to some embodiments of the present disclosure;

FIG. 3 is a schematic diagram of a package structure according to some embodiments of the present disclosure; and

FIG. 4 to FIG. 11 are schematic diagrams of a manufacturing process of a package structure according to some embodiments of the present disclosure.

### DETAILED DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

As used herein, terms such as “first”, “second”, and “third” describe various components, assemblies, regions, layers, and/or segments, which shall not be limited by such terms. These terms can be used simply to distinguish one component, assembly, region, layer, or segment from another. For example, the terms “first”, “second”, and “third” are used herein without implying an order or a sequence, unless clearly indicated by the context.

For ease of description, spatially relative terms such as “under”, “below”, “lower”, “above”, “over”, “upper” and the like may be used herein to describe a relationship of one component or feature to other components or features as illustrated in the accompanying drawings. It should be understood that the spatially relative terms are intended to encompass different orientations of the device in use or operation in addition to the orientation depicted in the accompanying drawings. For example, if the device in the accompanying drawings is turned over, components described as “below” or “under” other components or features would then be oriented “above” the other components or features. Therefore, the term “below” may include “above” and “below” orientations.

In this application, unless otherwise expressly specified and defined, terms such as “connect” and “connected to” should be understood in a broad sense. For example, unless otherwise expressly defined, a “connection” may be a fixed connection, may be a detachable connection, or may be an integrated connection; or may be a mechanical connection or an electrical connection; or may be a direct connection, or an indirect connection through an intermediate medium; or may be an inner connection between two components, or interaction between two components. A person of ordinary skill in the art may understand specific meanings of the foregoing terms in this application according to specific cases.

It should be noted that the terms “including”, “having”, or any other variant thereof in this application are intended to cover a non-exclusive inclusion.

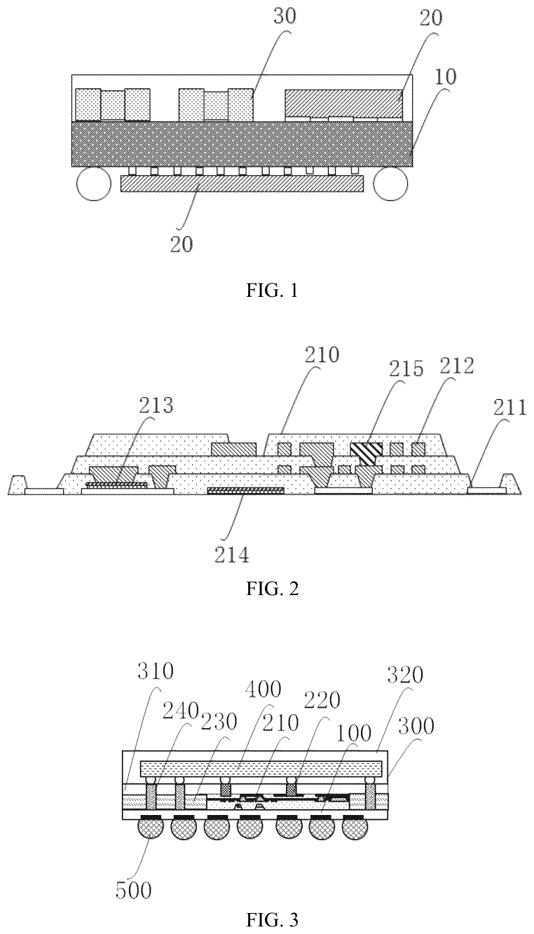

Referring to FIG. 1, an embodiment of this application provides a package structure, including:
a first redistribution structure 100;
a second redistribution structure 210 located on a surface of the first redistribution structure 100, where the second redistribution structure 210 includes a thin film passive component;
a first conductive pillar 220 located on a surface of the second redistribution structure 210;
a chip 400 located on a surface of the first conductive pillar 220; and
a molding layer 300 that is located on the surface of the second redistribution structure 210 and that encapsulates the chip 400 and the first conductive pillar 220.

In some embodiments, the first redistribution structure 100 includes a plurality of first redistribution layers, where the first redistribution layer includes a first dielectric layer and a first conductive line extending through the first dielectric layer. In some embodiments, the first redistribution structure 100 is a substrate. In some embodiments, the substrate may be a resin substrate, a ceramic substrate, a glass substrate, a silicon substrate, or a printed circuit board (PCB).

In some embodiments, referring to FIG. 2, the second redistribution structure 210 includes a plurality of second redistribution layers, where each second redistribution layer includes a second dielectric layer 211 and a second conductive line 212 extending through the second dielectric layer 211. In some embodiments, there is at least one thin film passive component, and the at least one thin film passive component is located at a corresponding second redistribution layer. In some embodiments, the thin film passive component may be a capacitor 213, a resistor 214, an inductor 215, or the like. It should be noted that the technology of integrating a thin film passive component into a redistribution structure is a conventional technology, which is not described in detail in this embodiment.

In some embodiments, a material of the first conductive pillar 220 may be one or more of aluminum, nickel, tin, tungsten, platinum, copper, titanium, chromium, tantalum, gold, or silver. In some embodiments, an electrical connection surface of the chip 400 faces the first conductive pillar 220. In some embodiments, the electrical connection surface of the chip 400 is a side surface that has a circuit structure.

In some embodiments, the chip 400 may be a logic chip and a memory chip. In some embodiments, the logic chip may include a gate array, a cell substrate array, an embedded array, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip, or a complementary metal-oxide-semiconductor (CMOS) image sensor. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)).

Referring to FIG. 3, the package structure according to some embodiments of the present disclosure further includes:
an insulation structure 230 that is located on the surface of the first redistribution structure 100 and that is also located on the outer side of the second redistribution structure 210; and a second conductive pillar 240 that is located on the surface of the first redistribution structure 100 and passes through the insulation structure 230, where the chip 400 is also located on a surface of the second conductive pillar 240, that is, the chip 400 is supported through the first conductive pillar 220 and the second conductive pillar 240. In some embodiments, heights of the first conductive pillar 220 and the second conductive pillar 240 may be the same. In some embodiments, the chip 400 is arranged on the surface of the first conductive pillar 220 and the surface of the second conductive pillar 240 through a solder layer. The chip 400 is electrically connected to the first redistribution structure 100 through the first conductive pillar 220 and the second redistribution structure 210, and the chip 400 is electrically connected to the first redistribution structure 100 through the second conductive pillar 240. In some embodiments, a material of the solder layer may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. In a conventional package structure, an electrical connection between the chip and the passive component can be realized through a line in the substrate. However, in the present disclosure, the chip 400 is directly connected to the passive component in the second redistribution structure 210 through the first conductive pillar 220, so that a transmission path of an electrical signal can be greatly shortened, and a transmission loss of the electrical signal is reduced.

In some embodiments, a material of the insulation structure 230 and a material of the second dielectric layer 211 in the second redistribution structure 210 may be the same. The insulation structure made of a same material as the second dielectric layer 211 in the second redistribution structure 210 is formed on the outer side of the second redistribution structure 210, so that stress balance is achieved between a combination of the insulation structure 230 in an edge area of the package structure and the second conductive pillar 240 and the second redistribution structure 210 in the middle area, and the package structure is prevented from warping due to stress imbalance.

In some embodiments, heights of the insulation structure 230 and the second redistribution structure 210 may be different. The height of the insulation structure 230 is adjusted, so that stress balance is more conveniently achieved between a combination of the insulation structure 230 in an edge area of the package structure and the second conductive pillar 240 and the second redistribution structure 210 in the middle area.

In some embodiments, a material of the second conductive pillar 240 may be one or more of aluminum, nickel, tin, tungsten, platinum, copper, titanium, chromium, tantalum, gold, or silver.

In some embodiments, a material of the molding layer 300 may be epoxy resin, polyimide resin, benzocyclobutene resin, or polybenzoxazole resin, and the forming process may be an injection molding process or a transfer molding process. In some embodiments, the molding layer 300 includes a first molding layer 310 and a second molding layer 320; the first molding layer 310 is located on the surface of the second redistribution structure 210 and a surface of the insulation structure 230, and the surface of the first conductive pillar 220 and the surface of the second conductive pillar 240 are exposed out of the first molding layer 310; and the second molding layer 320 is located on a surface of the first molding layer 310 and encapsulates the chip 400. In some embodiments, materials of the first molding layer 310 and the second molding layer 320 may be the same or different.

In some embodiments, solder balls 500 are arranged on a side surface that is of the first redistribution structure 100 and that is away from the second redistribution structure 210. In some embodiments, a material of the solder balls 500 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

Correspondingly, some embodiments of the present disclosure further provide a manufacturing method for a package structure, including:

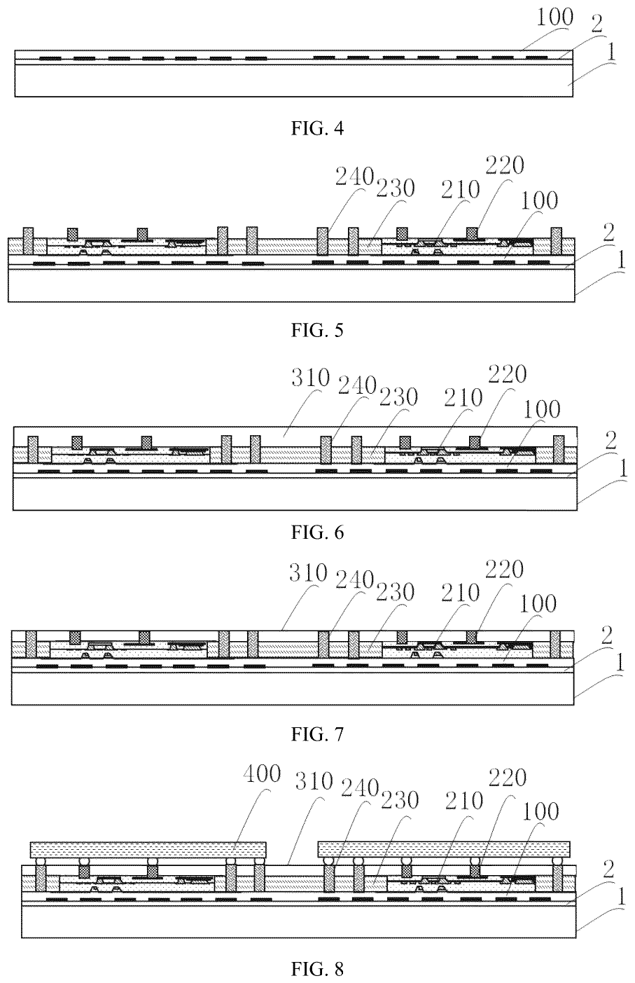

Referring to FIG. 4, a temporary carrier board 1 is provided; an adhesive layer 2 is formed on a surface of the temporary carrier board 1; and a first redistribution structure 100 is formed on a surface of the adhesive layer 2. In some embodiments, the step of forming the first redistribution structure 100 on the surface of the adhesive layer 2 includes: sequentially forming a plurality of first redistribution layers on the surface of the adhesive layer 2 to obtain the first redistribution structure 100, where the first redistribution layer includes a first dielectric layer and a first conductive line extending through the first dielectric layer. In some embodiments, the first redistribution structure 100 is a substrate. In some embodiments, the substrate may be a resin substrate, a ceramic substrate, a glass substrate, a silicon substrate, or a printed circuit board (PCB).

Referring to FIG. 5, a second redistribution structure 210 and a first conductive pillar 220 located on a surface of the second redistribution structure 210 are formed on a surface of the first redistribution structure 100, where the second redistribution structure 210 includes a thin film passive component. In some embodiments, the step of forming the second redistribution structure 210 and the first conductive pillar 220 located on the surface of the second redistribution structure 210 on the surface of the first redistribution structure 100 includes: sequentially forming a plurality of second redistribution layers on the surface of the first redistribution structure 100 and thin film passive components located at the second redistribution layers to obtain the second redistribution structure 210, and forming the first conductive pillar 220 on the surface of the second redistribution structure 210. In some embodiments, referring to FIG. 2, each second redistribution layer includes a second dielectric layer 211 and a second conductive line 212 extending through the second dielectric layer 211. In some embodiments, there is at least one thin film passive component, and the at least one thin film passive component is located at a corresponding second redistribution layer. In some embodiments, the thin film passive component may be a capacitor 213, a resistor 214, an inductor 215, or the like. In some embodiments, the step of forming the second redistribution structure 210 and the first conductive pillar 220 located on the surface of the second redistribution structure 210 on the surface of the first redistribution structure 100 includes: forming, on the surface of the first redistribution structure 100, the second redistribution structure 210, an insulation structure 230 located on the outer side of the second redistribution structure 210, and a second conductive pillar 240 passing through the insulation structure 230, and forming a first conductive pillar 220 on the surface of the second redistribution structure 210, where the first conductive pillar 220 and the second conductive pillar 240 are used for supporting the chip 400. In some embodiments, the second redistribution structure 210, the insulation structure 230, and the second conductive pillar 240 located in the insulation structure 230 are formed through stacking layer by layer. Specifically, the insulation structure 230 and the second conductive pillar 240 located in the insulation structure 230 may be formed through stacking layer by layer in the same process of forming the second redistribution structure 210, and then the first conductive pillar 220 is formed on the surface of the second redistribution structure 210, and a height of the second conductive pillar 240 is continuously increased, so that heights of the first conductive pillar 220 and the second conductive pillar 240 are the same. The second redistribution structure 210, the insulation structure 230, and the second conductive pillar 240 are formed through stacking layer by layer in the same process, so that stress balance is achieved between a combination of the insulation structure 230 in an edge area of the package structure and the second conductive pillar 240 and the second redistribution structure 210 in the middle area, and the package structure is prevented from warping due to stress imbalance. In some embodiments, heights of the insulation structure 230 and the second redistribution structure 210 may be different. The height of the insulation structure 230 is adjusted, so that stress balance is more conveniently achieved between a combination of the insulation structure 230 in an edge area of the package structure and the second conductive pillar 240 and the second redistribution structure 210 in the middle area.

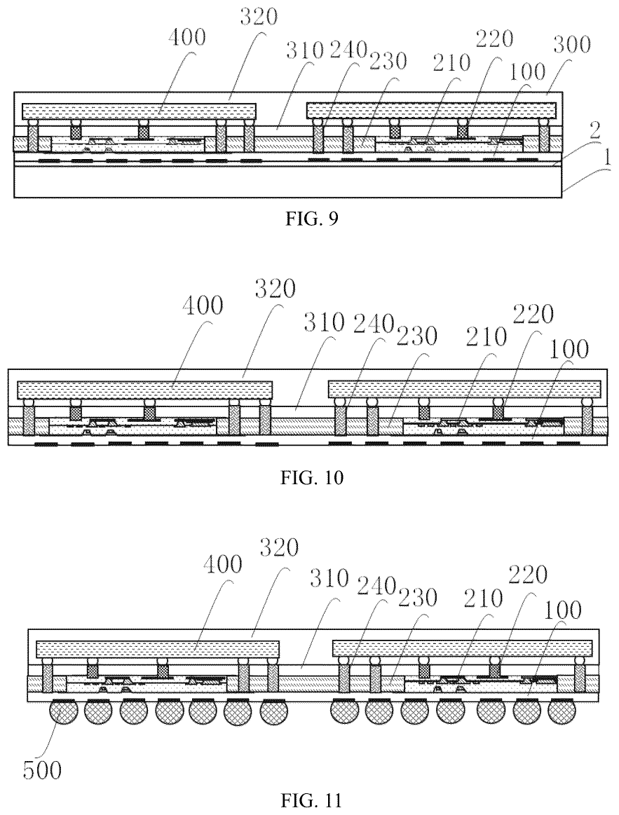

The chip 400 is formed on the surface of the first conductive pillar 220, and the molding layer 300 for packaging the chip 400 and the first conductive pillar 220 is formed on the surface of the second redistribution structure 210. In some embodiments, the step of arranging the chip 400 on the surface of the first conductive pillar 220 includes: arranging a solder layer of the chip 400 on the surface of the first conductive pillar 220. In some embodiments, a material of the solder layer may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. In some embodiments, the chip 400 may be a logic chip and a memory chip. In some embodiments, the logic chip may include a gate array, a cell substrate array, an embedded array, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip, or a complementary metal-oxide-semiconductor (CMOS) image sensor. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)). In some embodiments, the step of arranging the chip 400 on the surface of the first conductive pillar 220, and forming, on the surface of the second redistribution structure 210, the molding layer 300 for packaging the chip 400 and the first conductive pillar 220 includes: referring to FIG. 6, forming, on the surface of the second redistribution structure 210, the first molding layer 310 for packaging the first conductive pillar 220; and exposing the surface of the first conductive pillar 220 out of the first molding layer 310 (Specifically, referring to 7, the surface of the first conductive pillar 220 may be exposed out of the first molding layer 310 by grinding the surface of the first molding layer 310); referring to FIG. 8, arranging the chip 400 on the surface of the first conductive pillar 220; and referring to FIG. 9, forming, on the surface of the first molding layer 310, a second molding layer 320 for packaging the chip 400. In some embodiments, materials of the first molding layer 310 and the second molding layer 320 may be the same or different. In some embodiments, a material of the first molding layer 310 may be epoxy resin, polyimide resin, benzocyclobutene resin, or polybenzoxazole resin, and the forming process may be an injection molding process or a transfer molding process; and a material of the second molding layer 320 may be epoxy resin, polyimide resin, benzocyclobutene resin, or polybenzoxazole resin, and the forming process may be an injection molding process or a transfer molding process.

Referring to FIG. 6 to FIG. 9, in some embodiments, the step of arranging the chip 400 on the surface of the first conductive pillar 220, and forming, on the surface of the second redistribution structure 210, the molding layer 300 for packaging the chip 400 and the first conductive pillar 220 includes: forming, on the surface of the second redistribution structure 210, the first molding layer 310 for packaging the first conductive pillar 220 and the second conductive pillar 240; and thinning the first molding layer 310, so that surfaces of the first conductive pillar 220 and the second conductive pillar 240 are exposed out of the first molding layer 310; and arranging the chip 400 on the surfaces of the first conductive pillar 220 and the second conductive pillar 240. Specifically, the chip 400 is arranged on the surfaces of the first conductive pillar 220 and the second conductive pillar 240 through a solder layer; and forming, on a surface of the first molding layer 310, a second molding layer 320 for packaging the chip 400.

In some embodiments, the step after forming of the molding layer 300 further includes: referring to FIG. 10, removing a temporary carrier board 1 and an adhesive layer 2; and referring to FIG. 11, forming solder balls 500 on a side surface that is of the first redistribution structure 100 and that is away from the second redistribution structure 210. In some embodiments, a material of the solder balls 500 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

The present disclosure has been described with reference to the preferred embodiments, which are not used to limit the present disclosure. Those skilled in the art can make possible variations and modifications to the present disclosure using the disclosed methods and technical contents without departing from the spirit and scope of the present disclosure; and therefore, any simple modifications, equivalent changes and modifications made to the foregoing embodiments according to the technical spirit of the present disclosure without departing from the content of the technical solutions of the present disclosure shall fall within the protection scope of the technical solutions of the present disclosure.

What is claimed is:

1. A package structure, comprising:
a first redistribution structure;
a second redistribution structure located on a surface of the first redistribution structure, wherein the second redistribution structure comprises a thin film passive component;
a first conductive pillar located on a surface of the second redistribution structure;
a chip located on a surface of the first conductive pillar; and
a molding layer that is located on the surface of the second redistribution structure and that encapsulates the chip and the first conductive pillar.

2. The package structure according to claim 1, wherein the molding layer comprises a first molding layer and a second molding layer;
the first molding layer is located on the surface of the second redistribution structure, and encapsulates the second redistribution structure and the first conductive pillar, and the surface of the first conductive pillar is exposed out of the first molding layer; and
the second molding layer is located on a surface of the first molding layer and encapsulates the chip.

3. The package structure according to claim 1, wherein the second redistribution structure comprises a plurality of second redistribution layers; and each second redistribution layer comprises a second dielectric layer and a second conductive line extending through the second dielectric layer, and there is at least one thin film passive component.

4. The package structure according to claim 1, wherein solder balls are arranged on a side surface that is of the first redistribution structure and that is away from the second redistribution structure.

5. The package structure according to claim 1, further comprising:
an insulation structure that is located on the surface of the first redistribution structure and that is also located on the outer side of the second redistribution structure; and
a second conductive pillar that is located on the surface of the first redistribution structure and passes through the insulation structure, wherein the chip is also located on a surface of the second conductive pillar.

6. The package structure according to claim 5, wherein the molding layer comprises a first molding layer and a second molding layer;
the first molding layer is located on surfaces of the second redistribution structure and the insulation structure, and encapsulates the second redistribution structure, the insulation structure, the first conductive pillar, and the second conductive pillar, and the surface of the first conductive pillar and the surface of the second conductive pillar are exposed out of the first molding layer; and
the second molding layer is located on a surface of the first molding layer and encapsulates the chip.

7. The package structure according to claim 5, wherein heights of the insulation structure and the second redistribution structure may be different.

8. A manufacturing method for a package structure, comprising:
providing a temporary carrier board;
forming an adhesive layer on a surface of the temporary carrier board;
forming a first redistribution structure on a surface of the adhesive layer:
forming, on a surface of the first redistribution structure, a second redistribution structure and a first conductive pillar located on a surface of the second redistribution structure, wherein the second redistribution structure comprises a thin film passive component; and
arranging a chip on a surface of the first conductive pillar, and forming, on the surface of the second redistribution structure, a molding layer for packaging the chip and the first conductive pillar.

9. The manufacturing method for a package structure according to claim 8, wherein the step of forming, on the surface of the first redistribution structure, the second redistribution structure and the first conductive pillar located on the surface of the second redistribution structure comprises:
forming, on the surface of the first redistribution structure, a second redistribution structure, an insulation structure located on the outer side of the second redistribution structure, and a second conductive pillar passing through the insulation structure, and forming a first conductive pillar on the surface of the second redistribution structure, wherein the first conductive pillar and the second conductive pillar are used for electrically connecting to the chip.

10. The manufacturing method for a package structure according to claim 9, wherein the second redistribution structure, the insulation structure, and the second conductive pillar located in the insulation structure are formed through stacking layer by layer.

11. The manufacturing method for a package structure according to claim 8, wherein the step of arranging the chip on the surface of the first conductive pillar, and forming, on the surface of the second redistribution structure, the molding layer for packaging the chip and the first conductive pillar comprises:
forming, on the surface of the second redistribution structure, a first molding layer for packaging the first conductive pillar, wherein the surface of the first conductive pillar is exposed out of the first molding layer;
arranging the chip on the surface of the first conductive pillar; and
forming, on the surface of the first molding layer, a second molding layer for packaging the chip.

12. The manufacturing method for a package structure according to claim 8, the step after forming of the molding layer further comprises:
removing the temporary carrier board and the adhesive layer; and
forming solder balls on a side surface that is of the first redistribution structure and that is away from the second redistribution structure.
